(19) United States
(12) Patent Application Publication
(10) Pub. No.: US 2025/0112042 A1
(43) Pub. Date: Apr. 3, 2025

(54) METHOD, SYSTEM AND APPARATUS FOR FORMING ANISOTROPIC LAYER

(71) Applicant: ASM IP Holding B.V., Almere (NL)

(72) Inventors: Gregory Deye, Seattle, WA (US); Caleb Miskin, Mesa, AZ (US); Arun Murali, Tempe, AZ (US)

(21) Appl. No.: 18/900,134

(22) Filed: Sep. 27, 2024

Related U.S. Application Data
(60) Provisional application No. 63/586,890, filed on Sep. 29, 2023.

(51) Int. Cl. H01L 21/02; C30B 25/12; C30B 25/16; C30B 33/12

(52) U.S. Cl. CPC H01L 21/02636; C30B 25/12; C30B 25/165; H01L 21/02433; H01L 21/02576; H01L 21/02579; C30B 33/12

(57) ABSTRACT

A method, comprising supporting a substrate within a chamber of a semiconductor processing system, wherein the substrate comprises a feature including a surface having at least two first regions comprising silicon in an Si(110) crystal orientation and at least one second region comprising silicon in a non-Si(110) crystal orientation, wherein the at least one second region is disposed between the first regions, epitaxially growing a silicon-containing material on the at least two first regions in a Si(100) crystal orientation preferentially to the Si(110) crystal orientation and extending the silicon-containing material over the second region.

### CROSS-REFERENCE TO RELATED APPLICATION(S)

This Application claims the benefit of U.S. Provisional Application 63/586,890 filed on Sep. 29, 2023, the entire contents of which are incorporated herein by reference.

### FIELD OF INVENTION

The present disclosure generally relates to epitaxial treatment of a surface in semiconductor manufacturing. More particularly, the disclosure relates to a method, system and apparatus for forming an anisotropic layer on a semiconductor device feature.

### BACKGROUND OF THE DISCLOSURE

Semiconductor manufacturing of advanced semiconductor devices continues to increase the density of two- and three-dimensional features making performance increasingly reliant on precise epitaxial film deposition. The integrity of these layers is critical for achieving uniform device performance. Surface irregularities, non-conformal growth, low quality crystalline structures, and unwanted dopant behavior are some of the challenges of advanced semiconductor film deposition and epitaxial film growth.

While existing systems and methods have generally served their intended purposes there remains a need for improved methods to form structures that avoid the above-described challenges to enhance the performance and reliability of next generation semiconductor devices.

### SUMMARY OF THE DISCLOSURE

In one aspect, a method, includes supporting a substrate within a chamber of a semiconductor processing system, where the substrate includes a feature having a surface with at least two first regions in an Si(110) crystal orientation and at least one second region includes silicon in a non-Si(110) crystal orientation, wherein the at least one second region is disposed between the first regions, epitaxially growing a silicon-containing material on the at least two first regions in a Si(100) crystal orientation preferentially to the Si(110) crystal orientation, and extending the silicon-containing material over the second region.

In some examples, method may also include where the silicon-containing material includes a ratio of the Si(100) crystal orientation to the Si(110) crystal orientation of between about 1.6 and 3.5.

In various examples, the method may also include where a crystal structure of the silicon-containing material is substantially homogeneous in the Si(100) crystal orientation.

In some embodiments, the method may also include wherein the non-(110) crystal orientation is polycrystalline, amorphous, or a Si(111) crystal orientation, or a combination thereof. The method may also include extending the silicon-containing material over the second region to form a conformal layer of the silicon-containing material overlying the surface.

In certain examples, the method may also include where the first regions comprise monocrystalline silicon and/or may also include where the second region includes a dielectric material.

In certain examples, the method may also include where extending the silicon-containing material over the second region further includes forming a conformal layer of the silicon-containing material overlying the surface, where the conformal layer is an n-doped or p-doped barrier layer. Other technical features may be readily apparent to one skilled in the art from the following figures, descriptions, and claims.

In certain examples, the e method may also include where the dielectric material includes at least one of SiN, SiOxNy, and SiOx, or a combination thereof.

In certain examples, the method may also include where the dielectric material is a nitride or an oxide, or a combination thereof.

In certain examples, the method may also include where epitaxially growing the silicon-containing material further includes flowing a selective silicon precursor into the chamber, flowing one or more dopant-containing precursors into the chamber, and contacting the surface with the selective silicon precursor and the one or more dopant-containing precursors at a pressure of about 20 to 60 torr until a predetermined thickness of the conformal layer is achieved.

In an example, the method may also include where the selective silicon precursor is dichlorosilane (DCS).

In some embodiments, the method may also include where the predetermined thickness of the conformal layer is about 1.0 nm to about 10.0 nm.

In some examples, the method may also include where the one or more dopant-containing precursors comprise a p-type metal-oxide-semiconductor (pMOS) precursor includes diborane (B2H6) or boron trichloride (BCl3), or a combination thereof.

In certain examples, the method may also include where the one or more dopant-containing precursors are n-type metal-oxide-semiconductor (nMOS) precursors includes phosphine (PH3) or arsine (AsH3), or a combination thereof.

In various examples, the method may also include where the PH3 and the AsH3 are co-flowed. The method may also include where AsH3 is flowed without the PH3. The method may also include further includes inhibiting epitaxial growth of the silicon-containing material in the Si(110) crystal orientation, where inhibiting epitaxial growth of the silicon-containing material in the Si(110) crystal orientation further includes flowing HCl into the chamber, and etching the silicon-containing material in the Si(110) crystal orientation, where the selective silicon precursor and the HCl are co-flowed into the chamber in a ratio of about 1.5 to 6. Other technical features may be readily apparent to one skilled in the art from the following figures, descriptions, and claims.

In one aspect, a semiconductor processing system, includes a chamber configured to support a substrate, where the substrate includes a feature having a surface including at least two first regions includes silicon in a Si(110) crystal orientation and at least one second region includes silicon in a non-Si(110) crystal orientation, where the at least one second region is disposed between the first regions. The semiconductor processing system also includes a selective silicon precursor source, a first dopant source, a second dopant source and an etchant source connected to the chamber. The semiconductor processing system also includes a controller operably connected to the selective silicon precursor source, the first dopant source, the second dopant source, and the etchant source, where the controller, responsive to instructions recorded on a memory, is to support a substrate within the chamber at a pressure of about 20 to 60 torr, flow a selective silicon precursor into the chamber to contact the at least two first regions, form a silicon-containing material in a Si(100) crystal orientation on the at least two first regions where the silicon-containing material extends from the at least two first regions across the second region forming a continuous barrier layer over the surface to a predetermined thickness, flow one or more dopant-containing precursors into the chamber to deposit one or more dopant species in the silicon-containing material, and flow an etchant into the chamber to etch the silicon-containing material in the Si(110) crystal orientation.

The semiconductor processing system may also include where the continuous barrier layer includes a ratio of the Si(100) crystal orientation to the Si(110) crystal orientation of about 1.6 and 3.5, and where the selective silicon precursor is DCS, the one or more dopant-containing precursors are PH3 and AsH3, and the etchant is HCl. Other technical features may be readily apparent to one skilled in the art from the following figures, descriptions, and claims.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic diagram illustrating an example a semiconductor processing system;

FIG. 2 is a schematic diagram illustrating an example precursor delivery arrangement and exhaust arrangement;

FIG. 3 is a schematic diagram illustrating an example semiconductor processing chamber arrangement;

FIG. 4 is a schematic diagram illustrating an example method for depositing a material in accordance with an example of the present technology; and

FIG. 5A-5E are flow charts illustrating an example material deposition method for depositing a conformal layer of silicon-containing material onto a substrate.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

As used herein, the term “epitaxial layer” may refer to a substantially single crystalline layer upon an underlying substantially single crystalline layer or substrate.

As used herein, the term “chemical vapor deposition” may refer to any process wherein a substrate is exposed to one or more volatile precursors, which react and/or decompose on a substrate surface to form thereon a desired layer of material.

As used herein, the term “silicon-germanium” may refer to a semiconductor material comprising silicon and germanium and may be represented as SixGex.

As used herein, the terms such as Si(100), Si(110), Si(111) and the like refer to crystal orientations as denoted by Miller indices. Accordingly, a Si(100) substrate refers to a substrate comprising a surface area that is oriented along a (100) direction. Similarly, a Si(110) substrate refers to a substrate comprising a surface area that is oriented along a (110) direction. In some embodiment, the terms Si(100) substrate and Si(110) substrate refer to substrate having a surface along a (100) plane or a (110) plane, respectively. It shall be understood that the orientation of the respective substrate or surface area does not have to be perfect and can, for example, be off by a few degrees. For example, the orientation of the respective substrate or surface area may vary by about 0.1 degrees to 2.0 degrees, or by about 0.1 to 5.0 degrees, or by about 0.1 degrees to 10 degrees, or any appropriate variation.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

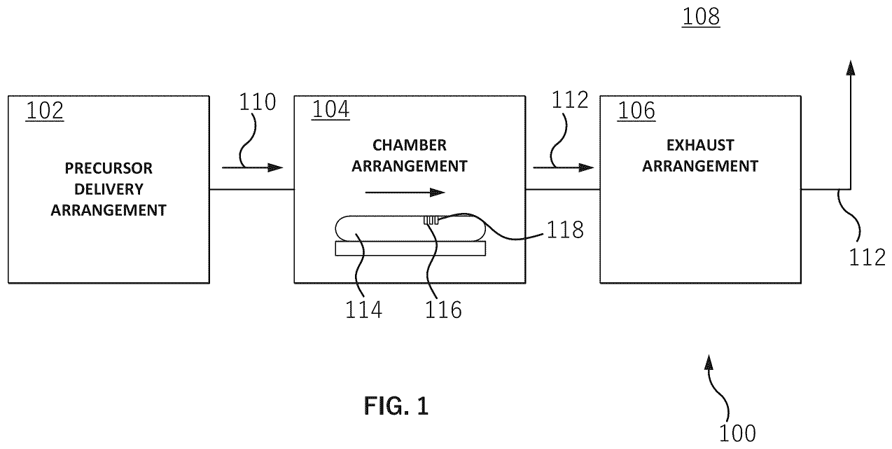

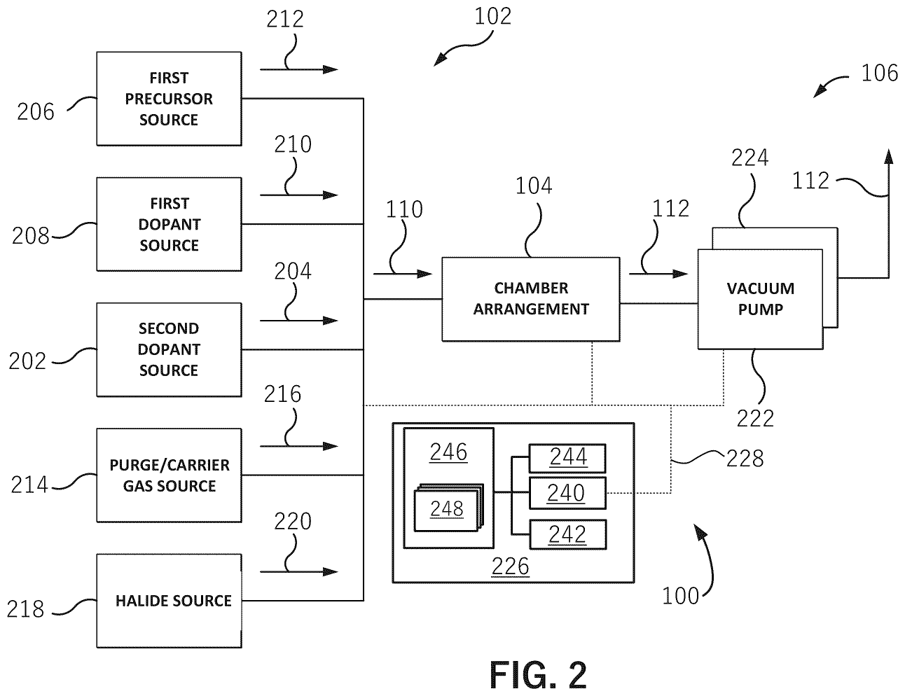

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases. Reference will now be made to the drawings wherein like reference numerals identify similar structural features or aspects of the subject disclosure. For purposes of explanation and illustration, and not limitation, a partial view of an example of a semiconductor processing system 100 in accordance with the present disclosure is shown in FIG. 1 and is designated generally by reference character 100. Other examples of chamber arrangements, semiconductor processing systems, and methods of depositing material layers onto substrates in accordance with the present disclosure, or aspects thereof, are provided in FIGS. 2-5E, as will be described.

The methods, system and apparatus of the present disclosure can be used for deposition of one or more anisotropic layers onto substrates, such as during the deposition of epitaxial material layers onto substrates during the fabrication of semiconductor devices, though the present disclosure is not limited to epitaxial material layers or to the fabrication of any particular type of semiconductor device.

With reference to FIG. 1, a semiconductor processing system 100 is shown. The semiconductor processing system 100 includes a precursor delivery arrangement 102, the chamber arrangement 104, and an exhaust arrangement 106. The precursor delivery arrangement 102 is connected to the chamber arrangement 104 and is configured to provide precursor 110 (precursor 110 is an abstraction intended to represent one or more precursors and/or other processing compounds) to the chamber arrangement 104. The chamber arrangement 104 is connected to the exhaust arrangement 106. Chamber arrangement 104, is configured to deposit a conformal layer 116 within a feature 118 onto a substrate 114 supported within the chamber arrangement 104 using the precursor 110 wherein the conformal layer 116. In an example, conformal layer 116 may comprise a silicon-containing material having a crystallographic orientation anisotropic to a growth surface upon which it is formed. The exhaust arrangement 106 is in fluid communication with the environment 108 external to the semiconductor processing system 100 and is configured to communicate a flow of residual precursor and/or reaction products 112 to the environment 108 external to the semiconductor processing system 100.

Semiconductor processing system 100 may be configured for processing of substrate 114 such as for epitaxial growth of an conformal layer 116 onto a substrate feature 118 including but not limited to high-performance devices such as gate-all-around (GAA), nanosheet, high aspect ratio trenches, and finFETs for NMOS and PMOS device fabrication. In an example, semiconductor processing system 100 may be operable for use for a variety of semiconductor processing techniques such as chemical vapor deposition (CVD) or atomic layer deposition (ALD) techniques.

With reference to FIG. 2, the precursor delivery arrangement 102, chamber arrangement and the exhaust arrangement 106 are shown. The precursor delivery arrangement 102 includes a first precursor source 206, a second precursor source 208, and a dopant source 202. The precursor delivery arrangement 102 also includes a purge/carrier gas source 214 and a halide source 218. The first precursor source 206 is connected to the chamber arrangement 104, includes a first precursor 212, and is configured to provide a flow of the first precursor 212 to the chamber arrangement 104. Non-limiting examples of suitable first precursors include dichlorosilane (H2SiCl2) and trichlorosilane (HCl3Si), and non-chlorinated silicon-containing precursors, such as silane (SiH4), disilane (Si2H6), tert-butylarsine (C4H9As), monomethyl silane (CH3SiH3), and/or trisilane (Si3H8).

In an example, the first dopant source 208 is connected to the chamber arrangement 104. The first dopant source 208, may include a first dopant-containing precursor 210, and is configured to provide a flow of the first dopant-containing precursor 210 to the chamber arrangement 104. Non-limiting examples of a suitable n-type dopant for use as the first dopant-containing precursor 210 include phosphorous (P), phosphine (PH3), arsine (AsH3), and/or phosphorus trichloride (PCl3). Non-limiting examples of a suitable p-type dopant 210 include diborane (B2H6) and/or boron trichloride (BCl3). In an example, GeH4 may be flowed with either B2H6 and/or BCl3.

In an example, the second dopant source 202 is connected to the chamber arrangement 104. The second dopant source 202, may include a second dopant-containing precursor 204, and is configured to provide a flow of the second dopant-containing precursor 204 to the chamber arrangement 104. Non-limiting examples of a suitable n-type dopant for use as the second dopant-containing precursor 204 include phosphorous (P), phosphine (PH3), arsine (AsH3), and/or phosphorus trichloride (PCl3). Non-limiting examples of a suitable p-type dopant 204 include diborane (B2H6) and/or boron trichloride (BCl3). In an example, GeH4 may be flowed with either B2H6 and/or BCl3.

In an example, the purge/carrier gas source 214 is further connected to the chamber arrangement 104, includes a purge/carrier gas 216, and is additionally configured to provide a flow of the purge/carrier gas 216 to the chamber arrangement 104. In this respect the purge/carrier gas source 214 may be configured to employ the purge/carrier gas 216 to carry one or more of the first precursor 212, the first dopant-containing precursor 210, and/or the second dopant-containing precursor 204 into the chamber arrangement 104. Examples of suitable purge/carrier gases include hydrogen (H2) gas, nitrogen (N2) gas, inert gases such as argon (Ar) gas or helium (He) gas, and mixtures thereof.

In an example, the halide source 218 is connected to the chamber arrangement 104, includes a halide-containing material 220, and is configured to provide a flow of the halide-containing material 220 to the chamber arrangement 104. The halide-containing material 220 may be co-flowed with precursor 212, first dopant-containing precursor 210 and/or second dopant 204. The halide-containing material 220 may be flowed independently from the precursors 210 or 212, such as to provide a purge and/or to remove condensate from within the chamber arrangement 104. Examples of suitable halides include chlorine (Cl), e.g., chlorine (Cl2) gas, dichlorosilane (H2SiCl2), trichlorosilane (H2SiCl2) and hydrochloric (HCl) acid, as well as fluorine (F), e.g., fluorine (F2) gas and hydrofluoric (Hf) acid.

In an example, the exhaust arrangement 106 is configured to evacuate the chamber arrangement 104 and in this respect may include one or more vacuum pumps 222 and/or an abatement apparatus 224. The one or more vacuum pumps 222 may be connected to the chamber arrangement 104 and configured to control pressure within the chamber arrangement 104. The abatement apparatus 224 may be connected to the one or more vacuum pump 222 and configured to process the flow a residual precursor and/or reaction products 112 issued by the chamber arrangement 104. It is contemplated that the exhaust arrangement 106 may be configured to maintain environmental conditions within the chamber arrangement 104 suitable for atmospheric deposition operations, such as pressures between about 1 Torr and about 800 Torr, such as during deposition of epitaxial material layers comprising monocrystalline silicon, for example, during deposition of conformal layer 116 within a feature 118 onto a substrate 114 (shown in FIG. 1). The exhaust arrangement 106 may also be configured to maintain environmental conditions within the exhaust arrangement 106 suitable for reduced pressure deposition operations, such as pressures between about 1 Torr and about 800 Torr, such as during the deposition of epitaxial material layers including using reduced pressure techniques.

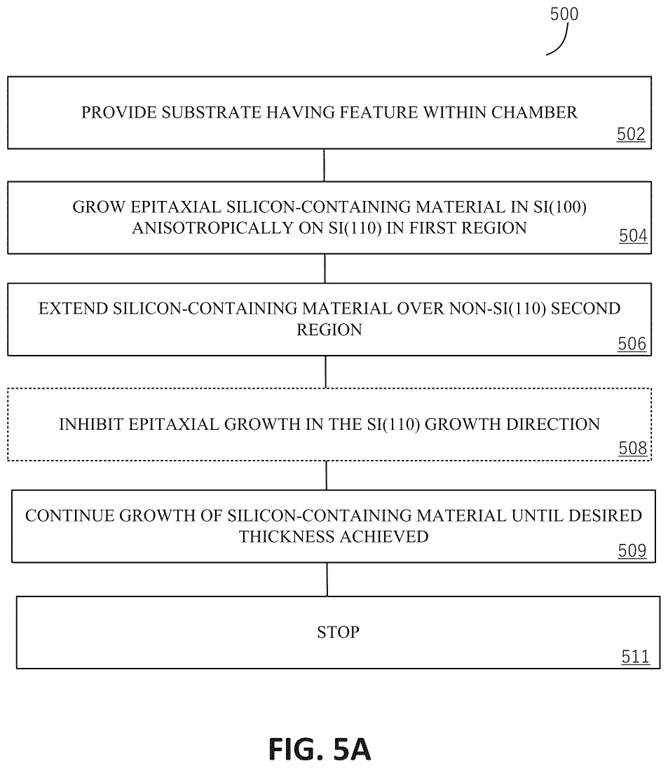

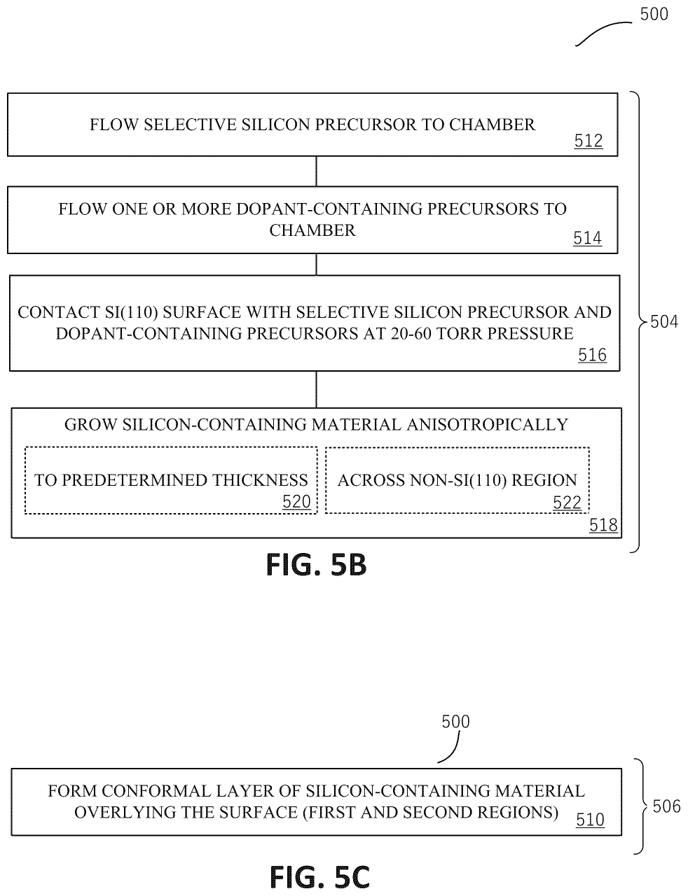

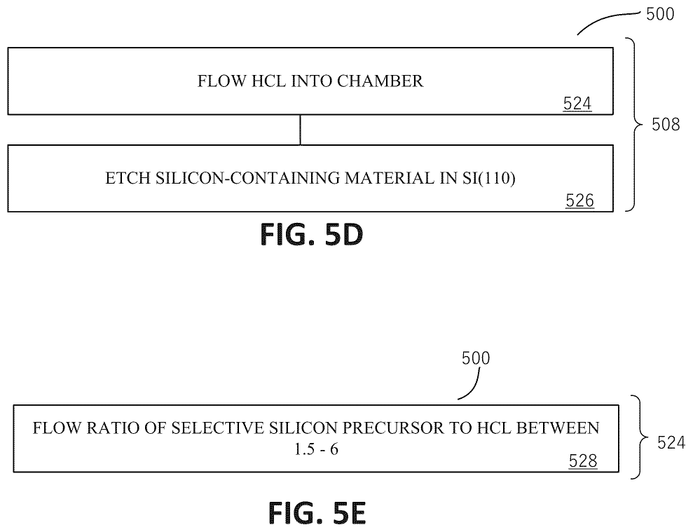

In an example, the precursor delivery arrangement 102, chamber arrangement and/or the exhaust arrangement 106, may be coupled to a system operation and control mechanism, controller 226. Controller 226 may provide electronic circuitry and mechanical components to selectively operate valves, manifolds, pumps and other equipment included in semiconductor processing system 100. Such circuitry and components operate to introduce precursor 212, first dopant-containing precursor 210, second dopant-containing precursor 204, purge/carrier gas 216 and halide-containing material 220 from the respective sources 206, 208, 202, 214 and 218. The controller 226 also controls timing of gas pulse sequences, temperature of the substrate and chamber, and pressure of the chamber and various other operations necessary to provide proper operation of the semiconductor processing system 100. Controller 226 can include control software and electrically or pneumatically controlled valves to control flow of precursors, reactants and purge gasses into and out of the chamber arrangement 104. Controller 226 includes a device interface 240, a processor 244, a user interface 242, and a memory 246. The device interface 240 connects the processor 244 to the wired or wireless link 228. The processor 244 is operably connected to the user interface 242 (e.g., to receive user input and/or provide user output therethrough) and is disposed in communication with the memory 246. The memory 246 includes a computer program product comprising a non-transitory machine-readable medium having one or more program modules 248 recorded thereon containing instructions that, when read by the processor 244, cause the processor 244 responsive to instructions to execute certain operations. Program modules 248 may comprise software, firmware and/or hardware components configured to performs certain tasks. Among the operations are operations of a structure forming method 500 (shown in FIGS. 5A-5E), as will be described. As will be appreciated by those of skill in the art in view of the present disclosure, the controller 226 may have a different arrangement in other examples and remain within the scope of the present disclosure.

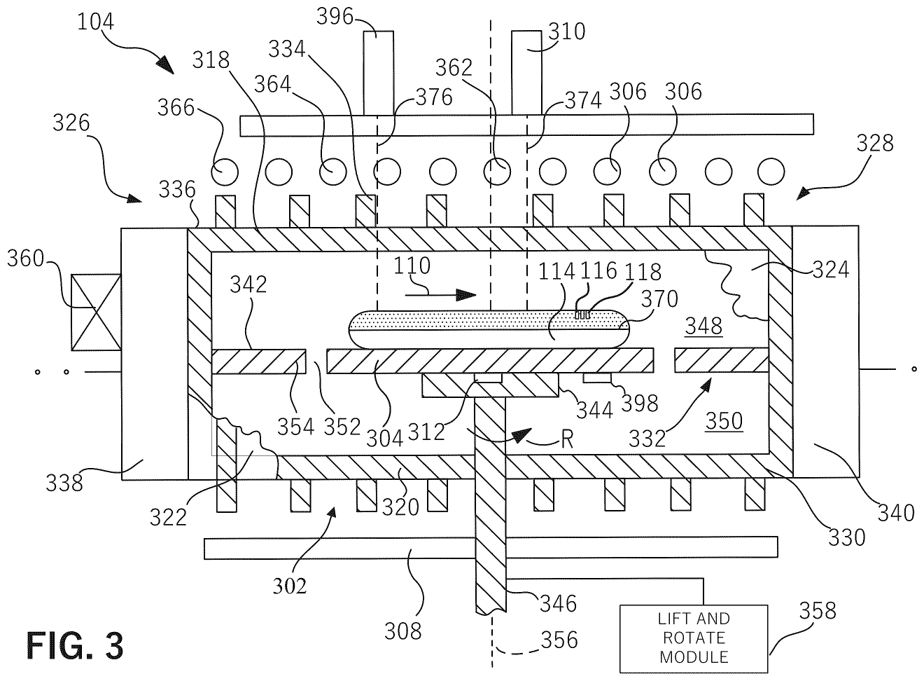

With reference to FIG. 3, the chamber arrangement 104 is shown. The chamber arrangement 104 includes a chamber 302 and a substrate support 304. The chamber arrangement 104 also includes an upper heater element array 306 and a lower heater element array 308. The chamber arrangement 104 further includes pyrometers 310 and 396, thermocouples 312 and 398, a controller 226 (shown in FIG. 2), and a wired or wireless link 228 (shown in FIG. 2). Although a specific arrangement is shown and described herein it is to be understood and appreciated that the chamber arrangement 104 may include other elements and/or omit elements shown and described herein and remain within the scope of the present disclosure.

In an example, the chamber 302 is configured to flow the precursors 110 (e.g., 212, first dopant-containing precursor 210, second dopant-containing precursor 204, purge/carrier gas 216 and halide-containing material 220 from the respective sources 206, 208, 202, 214 and 218 across the substrate 114 (see FIG. 2)). The chamber 302 has an upper wall 318, a lower wall 320, a first sidewall 322, and a second sidewall 324. The upper wall 318 extends longitudinally between an injection end 326 and a longitudinally opposite exhaust end 328 of the chamber 302, is supported horizontally relative to gravity, and is formed from a transmissive material 330. The lower wall 320 is below and parallel relative to the upper wall 318 of the chamber 302, is spaced apart from the upper wall 318 by an interior 332 of the chamber 302 and is also formed from the transmissive material 330. The first sidewall 322 longitudinally spans the injection end 326 and the exhaust end 328 of the chamber 302, extends vertically between the upper wall 318 and the lower wall 320 of the chamber 302, and is formed from the transmissive material 330. The second sidewall 324 is parallel to the first sidewall 322, is laterally opposite and spaced apart from the first sidewall 322 by the interior 332 of the chamber 302 and is further formed from the transmissive material 330. In certain examples, the transmissive material 330 may include a ceramic material such as sapphire and/or quartz. In accordance with certain examples, the chamber 302 may include a plurality of external ribs 334. The plurality of external ribs 334 may extend laterally about an exterior 336 of the chamber 302 and be longitudinally spaced between the injection end 326 and the exhaust end 328 of the chamber 302. In certain examples, one or more of the walls 318-324 may be substantially planar. In accordance with certain examples, one or more of the walls 318-324 may be arcuate or dome-like in shape. It is also contemplated that, in accordance with certain examples, the chamber 302 may include no ribs.

In an example, an injection flange 338 and an exhaust flange 340 may be connected to the injection end 326 and the exhaust end 328, respectively, of the chamber 302. The injection flange 338 may fluidly couple the precursor delivery arrangement 102 (shown in FIG. 1) to the interior 332 of the chamber 302 and be configured to provide the precursor 110 to the interior 332 of the chamber 302. The exhaust flange 340 may fluidly couple the interior 332 of the chamber 302 to the exhaust arrangement 106. The exhaust flange 340 may be configured to communicate the residual precursor and/or reaction products 112 (shown in FIG. 1) issued by the chamber arrangement 104 during deposition of the conformal layer 116 and/or other deposition layers (see FIG. 1) onto the substrate 114. In this respect the chamber 302 may have a cold wall, cross-flow reactor configuration.

In an example, a divider 342, a support member 344, and a shaft member 346 may be arranged within the interior 332 of the chamber 302. The divider 342 may be fixed within the interior 332 of the chamber 302 and divide the interior 332 of the chamber 302 into an upper chamber 348 and a lower chamber 350. The divider 342 may further define an aperture 352 therethrough, the aperture 352 fluidly coupling the upper chamber 348 of the chamber 302 to the lower chamber 350 of the chamber 302. The divider 342 may be formed from an opaque material 354. The opaque material 354 may include silicon carbide.

In an example, the substrate support 304 may be configured to seat thereon the substrate 114 and is supported at least partially within the aperture 352 for rotation R about a rotation axis 356. The substrate support 304 may seat the substrate 114 such that a radially-outer peripheral portion of the substrate 114 abuts the substrate support 304 while a radially-inner central portion of the substrate 114 is spaced apart from the substrate support 304. The support member 344 may be arranged below the substrate support 304 and along the rotation axis 356. The support member 344 maybe further arranged within the lower chamber 350 of the chamber 302 and fixed in rotation relative to the substrate support 304 about the rotation axis 356 for rotation with the substrate support 304. The substrate support 304 may be formed from an opaque material, such as the opaque material 354 or a graphite material. The support member 344 may be formed from a transmissive material, such as the transmissive material 330.

In an example, the shaft member 346 may be arranged along the rotation axis 356 and fixed in rotation relative to the support member 344 about the rotation axis 356. The shaft member 346 may also extend through the lower chamber 350 of the chamber 302 and through lower wall 320 of chamber 302. The shaft member 346 may further operably connect a lift and rotate module 358 to the substrate support 304, the lift and rotate module 358 in turn may be configured to rotate R the substrate support 304 and the substrate 114 about the rotation axis 356 during deposition of the conformal layer 116 within feature 118 of substrate 114. The lift and rotate module 358 may further cooperate with a gate valve 360 and a lift pin arrangement to seat and unseat the substrate 114 from the substrate support 304, such as through a substrate handling robot arranged within a cluster-type platform in selective communication with the interior 332 of the chamber 302 through the gate valve 360. In certain examples the shaft member 346 may be formed from a transmissive material, such as the transmissive material 330.

As the semiconductor industry continues to seek advanced performance of semiconductor devices at ever-shrinking geometries, the density of 3-dimensional architectures (e.g., nano-wire and nano-features) continues to increase. In conventional epitaxial substrate processing, epitaxial growth rates may vary depending upon the condition of the growth surface. Growth surfaces having different growth rates can lead to variance in thickness, electrical, chemical and overall quality characteristics in epitaxial layers grown over such surfaces. For example, growth rates vary between Si(100) vs Si(110) surfaces in coherent silicon, various surface regions across polycrystalline and/or amorphous surfaces may have varied growth rates due to a variety of factors and growth rates may vary between surfaces having different materials.

In an example, in the instance of gate-all-around fin structures including monocrystalline silicon layered with adjacent dielectric layers, growth will more likely proceed off of the coherent silicon because the dielectric material will present a sizeable nucleation delay compared to coherent silicon. Overall, the epitaxial barrier layer plays a critical role in optimizing the performance reliability and scalability of GAA transistors which are a key component in advanced semiconductor technology. By carefully controlling the crystalline growth and quality desired electrical characteristics and dopant behavior can be improved over conventional methods to enable continued advancing performance while reducing device size.

In an example, one method to achieve better control of epitaxial growth on surfaces having different growth rates or other growth impacting characteristics is to set-up process parameters giving rise to anisotropic growth (i.e., crystal growth in one crystallographic orientation off of a plane in a different crystallographic orientation (e.g., growth in the Si(100) over a surface in the Si(110)) may support tuning of growth rates to enable control over crystal growth conformality, quality, and/or propensity to diffuse dopants to further 2- and 3-dimensional device density scaling.

To reduce one or more of the above noted defects in epitaxial growth and/or uniformity over surfaces having differing growth rates, methods, apparatus, systems and processes for making semiconductor devices enabling selective epitaxial growth in an anisotropic direction, improved control of crystalline quality and/or dopant diffusion are disclosed herein. Such methods, apparatus, systems and processes may improve conformality of epitaxial layers, crystal quality and/or electrical performance of such devices. In some example, the methods and processes may be paired with an etching process to maximize net anisotropic growth.

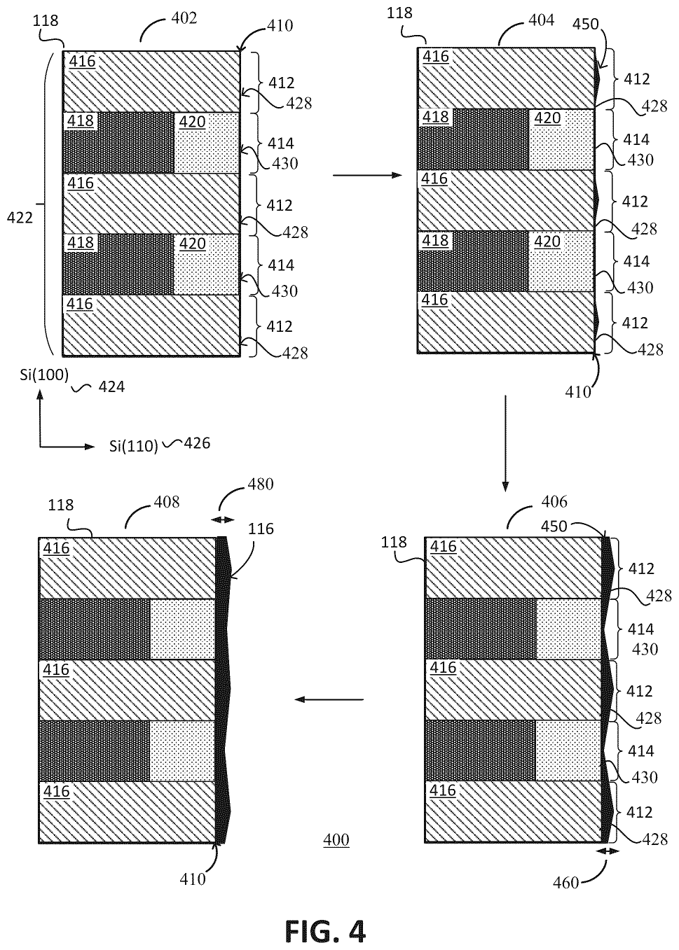

FIG. 4 illustrates an example process 400 for depositing a silicon-containing material onto a feature fabricated on a substrate 114 to form a layer of the silicon-containing material over feature 118 according to examples of the present technology. For simplicity, process 400 will be described with reference to FIGS. 1-4. Reference to FIGS. 1-3 is provided for clarity and is not intended to limit claimed subject matter. Other systems, apparatus, and arrangements of components operable to perform the presently disclosed process are contemplated and within the scope of the disclosure.

In an example, at operation 402 a substrate (e.g., substrate 114) may be provided within a chamber (e.g., chamber 302) of a semiconductor processing system (e.g., processing system 100).

In an example, one or more features 118 maybe fabricated on substrate 114 within chamber 302. Alternatively, substrate 114 may be provided to chamber 302 with feature 118 present, or a combination thereof.

In an example, feature(s) 118 may comprise any of a variety of features that may be formed on a substrate by any of a variety of processes known to those of skill in the art. For example, feature(s) 118 may be a two-dimensional feature such as a contact, nanosheet, and/or gate oxide, and/or three-dimensional feature such as a trench, via, nanowire, and/or a fin structure (e.g., planar FET, finFET, and/or gate-all-around (GAA) FET) and claimed subject matter is not limited in this regard.

In an example, feature 118 comprises a GAA fin comprising a stack 422 of alternating layers of silicon-containing material. For example, stack 422 may comprise one or more layers of monocrystalline silicon (Si) 416 alternating with one or more layers of silicon germanium (SiGe) 418. Stack 422 may include spacers 420 disposed between monocrystalline silicon (Si) layers 416 and adjacent to (SiGe) layers 418. Spacers 420 may comprise a dielectric material, such as, for example a nitride and/or an oxide. In an example, spacer 420 may comprise silicon nitride (SiN), silicon oxynitride (SiOxNy), and/or silicon oxide (SiOx), or the like, or a combination thereof, or any other appropriate material known to those of skill in the art. In an example, spacers 420 can serve a variety of functions in a FET depending on the specific purpose of the device. In various examples, among other functions, spacers 420 may define a channel region in a GAA FET, contribute to electrical isolation between the gate and channel, impact threshold voltage, and/or may help prevent electrical leakage.

In an example, feature 118 may comprise a surface 410 having one or more first regions 412 comprising an Si(110) crystal orientation 426 and one or more second regions 414 comprising silicon in a non-Si(110) crystal orientation (e.g., Si(100) crystal orientation, Si(111) crystal orientation, polycrystalline, or amorphous, or a combination thereof). At least one second region 414 may be disposed between two first regions 412.

In an example, first regions 412 may comprise respective surfaces 428 of monocrystalline Si layers 416 such that first regions 412 are surfaces in the Si(110) crystal orientation 426.

Likewise, second regions 414 may comprise respective surfaces 430 of spacers 420 such that second regions 414 are surfaces in a non-Si(110) crystal growth orientation.

In an example, at operation 404, a silicon-containing material 450 may be grown epitaxially on one or more first regions 412 or two or more first regions 412. In an example, a silicon-containing material 450 may be grown epitaxially, using selective process conditions such that little to no silicon-containing material 450 forms on surface 430 within second region 414. Such process conditions may be tuned to preferentially form silicon-containing material 450 on the at least two first regions 412.

In an example, the silicon-containing material 450 is exposed to epitaxial growth conditions favoring growth in the Si(100) crystal orientation. Under such conditions, silicon-containing material 450 may comprise a deposition ratio preferential to deposition in the Si(100) crystal orientation 424 over Si(110) crystal orientation 426. Growth of silicon-containing material 450 having the Si(100) crystal orientation on a surface having a Si(110) crystal orientation is referred to herein as “anisotropic” growth. Thus, silicon-containing material 450 is formed anisotropically in the Si(100) crystal orientation 424 on one or more first regions 412 having an Si(110) crystal orientation. Moreover, such preferential growth of silicon-containing material 450 in the Si(100) crystal orientation 424 enables growth of silicon-containing material 450 having a silicon crystal structure in a ratio of Si(100) crystal orientation 424 to Si(110) crystal orientation 426 of between about 1.6 and 3.5. In an example, the Si(100):Si(110) ratio of silicon-containing material 450 depends on the process condition and may be tuned to meet the specification of a particular device. In some examples, silicon-containing material 450 grown anisotropically on region 412 may comprise a substantially homogeneous Si(100) crystal structure wherein there is no Si(110) crystal structure in the silicon-containing material 450 or the amount is negligible (e.g., less than 1%, or less than 0.5% or less than 0.01%).

In an example, continuing at operation 404 epitaxially growing the silicon-containing material 450 may include flowing a selective silicon precursor 212 from precursor source 206 into the chamber 302 to contact surface 410. In an example, the selective silicon precursor may be dichlorosilane (DCS), and/or disilane (Si2H6) and hydrogen chloride (HCl). In an example, other chlorinated silicon-containing precursors may be used such as, for example, monochlorosilane (MCS), trichlorosilane (TCS), hexachlorodisilane (HCDS), octachlorotrislane (OCS), and/or silicon tetrachloride (STC). In an example, hydrogenated silicon-containing precursors may be used, for example, silane (SiH4), trisilane (Si3H8), and/or tetrasilane (Si4H10).

In an example, silicon-containing material 450 may be n- or p-doped. Accordingly, epitaxially growing the silicon-containing material 450 may include flowing a first dopant-containing precursor 210 from dopant source 208 to chamber 302 to contact surface 410. In an example, first dopant-containing precursor 210 can be any of a variety of compounds including n-type metal-oxide-semiconductor (nMOS) precursors comprising phosphine (PH3) or arsine (AsH3), or a combination thereof. In an example, a single dopant-containing precursor may be used (e.g., AsH3 can be flowed without PH3). In this case, for example, silicon-containing material 450 may be formed comprising SiAs. In a non-limiting example, a single dopant-containing precursor is supplied (e.g., AsH3), silicon-containing material 450 may be grown to have a concentration of As within the silicon lattice of between about 1e20 at/cm³ to 1e21 at/cm³.(“about” in this context is plus or minus 20% the upper and lower concentration values). Other appropriate concentrations may be used, are contemplated and claimed subject matter is not limited in this regard.

In an example, continuing at operation 404 epitaxially growing the silicon-containing material 450 may include flowing a second dopant-containing precursor 204 from second dopant source 202 to chamber 302 to contact surface 410. Second dopant-containing precursor 210 can be any of a variety of compounds including but not limited to n-type metal-oxide-semiconductor (nMOS) precursors. PH3 and AsH3 may both be used as dopant materials; and precursors containing PH3 and/or AsH3 may be co-flowed during process 400 to epitaxially grow silicon-containing material 450. In a non-limiting example, where two dopant-containing precursors are supplied (e.g., AsH3 is co-flowed with PH3), silicon-containing material 450 may be grown to comprise SiAsP having a concentration of As within the silicon lattice of between about 1e20 at/cm³ to 1 e21 at/cm³ and a concentration of P of between about 1e20 at/cm³ to 1e21 at/cm³ (“about” in this context is plus or minus 20% the upper and lower concentration values). Other appropriate concentrations may be used, are contemplated and claimed subject matter is not limited in this regard.

In another example, first dopant-containing precursor 210 can be any of a variety of compounds including p-type metal-oxide-semiconductor (pMOS) precursor comprising diborane (B2H6), boron trichloride (BCl3), or the like or a combination thereof. In an example, germanium hydride (GeH4) may be co-flowed with B2H6 and/or BCl3 to form silicon-containing material 450 comprising SiGeB. In this example, a concentration of B within the silicon lattice of silicon-containing material 450 comprising SiGeB may be between about 1e20 at/cm³ to 1e21 at/cm³ (“about” in this context is plus or minus 20% the upper and lower concentration values). Other appropriate concentrations maybe used, are contemplated and claimed subject matter is not limited in this regard.

In an example, continuing at operation 404 epitaxially growing the silicon-containing material 450 may include flowing an etchant into chamber 302 prior to inhibit epitaxial growth of the silicon-containing material 450 in the Si(110) crystal orientation. The etchant may be flowed concurrently with, and/or subsequent to flowing precursor 212, first dopant-containing precursor 210, and/or second dopant-containing precursor 204 into chamber 302. Etchant may comprise a halide-containing material 220 provided to chamber 302 from halide source 218. Halide-containing material 220 may contact silicon-containing material 450, and/or regions 412, 414 of feature 118. Halide-containing material 220 may preferentially etch impurities, flaws and/or errors in the crystal lattice of the anisotropically grown silicon-containing material 450 during process 400. Exposing silicon-containing material 450 to halide-containing material 220 may inhibit epitaxial growth of the silicon-containing material 450 in the Si(110) crystal orientation and/or may etch silicon-containing material 450 in the Si(110) crystal orientation.

In an example, inhibiting epitaxial growth of the silicon-containing material 450 in the Si(110) crystal orientation may be further enabled by concurrently flowing DCS and HCl into the chamber in a ratio in the range of about 1.5 to 6. In an example, the optimal DCS to HCl depends on factors such as temperature and specific growth rate regime.

In an example, etching the silicon-containing material in the Si(110) crystal orientation may be further intensified by concurrently flowing HCl and the first dopant-containing precursor and/or the second dopant containing precursor. In certain examples, without being tied to a particular theory, dopants may accumulate in errors or defects in the crystal lattice inducing preferential etching in such areas.

At operation 406 as process 400 continues, silicon-containing material 450 may grow over one or more second regions 414 covering one or more second surface(s) 430.

At operation 408, silicon-containing material 450 may grow to a predetermined thickness to form a conformal layer 116 of the silicon-containing material 450 overlying the surface 410.

In an example, operation 408 may include contacting the surface 410 with the selective silicon precursor 212, first dopant-containing precursor 210, second dopant-containing precursor 204 and/or halide-containing material 220 in any order, concurrently, repeatedly, and/or sequentially for any amount of time until a predetermined thickness and coverage of the silicon-containing material 450 over surface 410 is achieved.

In an example, at operation 408 silicon-containing material 450 may continue to grow anisotropically overlying the surface 410 and become highly uniform forming a conformal layer 116 wherein the conformal layer 116 thickness 480 varies little over surface 410. In an example, conformal layer 116 may be grown to a depth of about 0.5 nm to about 30 nm, or about 0.5 nm to about 20 nm, or about 0.5 nm to about 15 nm, or about 0.5 nm to about 10.0 nm, or about 0.5 nm to about 6.0 nm, or about 0.5 nm to about 5.0 nm, or about 0.5 nm to about 3.0 nm (“about” in this context means plus or minus 2.0 nm), or any other suitable thickness.

In an example, during process 400 silicon-containing material 450 growth rates depend on specific process parameters and may vary widely. In some examples, the growth rates may be about 5.0 Å/m, or about 15.0 Å/m, or about 25.0 Å/m, or about 35.0 Å/m, or about 45.0 Å/m, or about 100.0 Å/m, or any suitable growth rate and claimed subject matter is not limited in this regard. In an example, a desired thickness, which may be predetermined, of silicon-containing material 450 anisotropically grown forming a conformal layer 116 of about 5.0 nm may take from 0.1 to 5 minutes, or from 5 to 15 minutes, or from 10 to 20 minutes, or from 15 to 30 minutes, or from 20 to 40 minutes or from 30 to 45 minutes, or from 40 to 60 minutes (“about” in this context means plus or minus 5 minutes), or any appropriate time.

Thus, during process 400, in order to grow a layer of silicon-containing material 450 to a desired layer thickness (e.g., 5.0 nm), exposure time to precursors and dopants (such as those discussed previously herein) may be tuned according to the desired thickness based on a growth rate regime. In an example, because silicon tends to grow slower from surfaces in the Si(110) crystal orientation than in the Si(100) crystal orientation, a growth rate may be slower for Si(100) crystal structures grown anisotropically from Si(110). However, impact on throughput is reduced when the anisotropic layer is thin. Moreover, Si(100) crystal structure is higher in electrical characteristics and film quality, less prone to defects and diffusion of dopants than Si(110) crystal structure.

At operation 408, the predetermined thickness 480 of conformal layer 116 is about 0.5 nm to about 20.0 nm thick or about 1.0 to about 15.0 nm thick or about 1.0 to about 5.0 nm thick or about 1.0 nm to about 3.0 nm thick.

In an example, once conformal layer 116 has grown to a predetermined thickness 480 may provide a barrier to dopant diffusion preventing leakage and other failure modes.

In an example, during process 400 pressure within chamber 302 may be about 1.0 torr to about 800.0 torr. In some examples, a predetermined deposition pressure may be maintained within chamber 302 during process 400. For example, the predetermined pressure may be between about 1 torr and about 400 torr, or between about 5 torr and about 300 torr, or between about 10 torr and about 300 torr, or between about 50 torr and about 300 torr, or between about 100 torr and about 300 torr, or between about 150 torr and about 300 torr, or between about 200 torr and about 300 torr, or any other appropriate pressure. In various examples, one or more operations 404, 406 and 408 of process 400 may comprise contacting the surface 410 with the selective silicon precursor, the one or more dopant-containing precursors, and the halide at a predetermined pressure of between about 200 torr 300 torr.

In certain examples, pressure within the interior of chamber 302 may be maintained at less than about 400 torr, or less than about 300 torr, or less than about 275 torr, or less than about 260 torr, or less than about 200 torr or less than about 100 torr, or less than about 50 torr, or less than about 40 torr, or even less than about 30 torr during process 400. The predetermined deposition pressure may be between about 200 torr 300 torr, (“about” in this context means plus or minus 20 torr).

In an example, during process 400, chamber 302 may be heated to a temperature of between about 250° C. to about 800° C., or between about 300° C. to about 775° C., or between about 400° C. to about 750° C., or between about 500° C. to about 725° C., or between about 550° C. to about 700° C., for example 650° C. (“about” in this context means plus or minus 25° C.), or any appropriate temperature. Heating and pressurization of chamber 302 may be controlled by controller 226.

As will be appreciated by those of skill in the art in view of the present disclosure, controller 226 (see FIG. 2) can monitor and control various processes and equipment comprising semiconductor processing system 100 (see FIG. 1) in the production of semiconductor materials. Controller 226 (see FIG. 2) receives input from sensors and other devices that measure various parameters, such as temperature, pressure, and flow rate, and uses this information to adjust the operation of the equipment and processes as needed. Controller 226 may control temperature and pressure settings and the flow of gases or liquids through the semiconductor processing system 100 (see FIG. 1) which is important to controlling the growth of epitaxial layers by regulating the parameters that affect its growth. Controller 226 (see FIG. 2) may be programmed to perform other tasks, specific functions and capabilities of a controller in a substrate processing system will depend on the specific requirements of the application.

In an example, substrate 114 may be provided in chamber 302 (see FIG. 3) of a semiconductor processing system 100 (see FIG. 1). Operation 404 may be initiated by controller 226 triggering precursor 212, the first dopant-containing precursor and/or the second dopant containing precursor and halide-containing material 220 to flow into chamber 302 and to contact surface 428 to anisotropically grow doped epitaxial silicon-containing material 450. Controller 226 may operations 406-408 to control growth of silicon-containing material to a predetermined thickness over regions 412 and extending the doped silicon-containing material 450 over regions 414 such that a conformal barrier layer is formed over surface 410.

The following examples refer to FIGS. 5A-5E depicting flowcharts illustrating a method 500 describing a process of depositing a material onto a substrate 114 to form an anisotropic conformal layer 116 on a surface 410 (see FIG. 4) wherein the conformal layer 116 comprises a ratio of Si(100) to Si(110) of greater than 1.5. In an example, method 500 may proceed in a chamber arrangement, for example chamber arrangement 104 (see FIG. 1). FIGS. 5A-5E illustrate various operations of a material deposition method 500 that may in some examples be executed by controller 226. More specifically, operations of method 500 may be controlled and/or executed by controller 226 to selectively operate valves (e.g., gate valve 360 illustrated in FIG. 3), flanges (e.g., flanges 338 and 340), manifolds, pumps, substrate support 304, lift and rotate module 358, heating elements (e.g., heater element arrays 306 and 308), temperature sensors (e.g., pyrometers 310 and 396 and thermocouples 312 and 398), silicon-controlled rectifier (SCR) devices and other equipment included in semiconductor processing system 100 (see FIG. 1).

FIG. 5A is a flow chart illustrating an example material deposition method 500. In an example, method 500 may begin at block 502 where a substrate 114 having a feature 118 (see FIG. 4) may be supported within chamber 302 (see FIG. 3) of a semiconductor processing system 100 (see FIG. 1).

Method 500 may proceed to block 504, where epitaxial silicon-containing material 450 may be grown anisotropically (e.g., grown in the Si(100) on a Si(110) surface) on one or more first regions 412 (see FIG. 4).

Method 500 may proceed to block 506, where silicon-containing material 450 may be extended due to continued anisotropic growth on region 412 in the Si(100) across non-Si(110) areas in one or more second regions 414 (see FIG. 4).

Method 500 may proceed to block 508, where growth of the silicon containing material may be inhibited by use of an etchant. Such inhibition may promote growth of higher quality silicon crystal while reducing incidence or errors, defects or formation of crystal structure in unwanted crystal orientation, such as Si(111).

At block 509, silicon-containing material 450 may be grown to a predetermined thickness (e.g., 5 nm), the thickness may be substantially even across surface 410 due to growth and concurrent etch-back to forming a conformal layer 116 over surface 410. Method 500 may stop at block 511.

Referring now to FIG. 5B where example operations for block 504 of method 500 (see FIG. 5A) are further illustrated in a flow chart. At block 512, selective precursor 212 may be flowed into chamber 302. At block 514, one or more dopant-containing precursors 210 and/or 204 may be flowed into chamber 302 (see FIG. 3). At block 516, dopant-containing precursors 204 and/or 210 may be co-flowed with precursor 212 at a pressure of about 20-60 torr. At block 518, silicon-containing material may be grown anisotropically to a predetermined thickness (block 520) and/or across non-Si(110) region 414 (at block 522).

FIG. 5C is a further example operation for block 506 of method 500 (see FIG. 5A). At block 510, a conformal layer 116 of silicon-containing material 450 may be formed overlying the surface 410 (e.g., over first region 412 and second regions 414) wherein the conformal layer 116 thickness 480 varies less than about 15% across surface 410, or less than about 10% across surface 410, or less than about 5% across surface 410, or less than about 1% across surface 410, or less than about 0.1% across surface 410 (“about” in this context means plus or minus 2%).

FIG. 5D is a flowchart showing further example operations for block 508 of method 500 (see FIG. 5A). At block 524, a halide-containing material 220 may be provided to the chamber. The halide may comprise HCl or other etchant species. The ration of selective silicon precursor 212 to halide-containing material 220 may between 1.5-6. At block 526, the halide-containing material 220 may etch silicon-containing material 450.

FIG. 5E a further example operation for block 524 of method 500 (see FIG. 5D). At block 528, flow selective silicon precursor 212 and halide-containing material 220 into chamber in a ration of about 1.5 to about 6.

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various processes, systems, and configurations, and other features, functions, acts, and/or properties disclosed herein, as well as any and all equivalents thereof.

1. A method, comprising:
supporting a substrate within a chamber of a semiconductor processing system,
wherein the substrate comprises a feature including a surface having at least two first regions comprising silicon in an Si(110) crystal orientation and at least one second region comprising silicon in a non-Si(110) crystal orientation, wherein the at least one second region is disposed between the first regions;
epitaxially growing a silicon-containing material on the at least two first regions in a Si(100) crystal orientation preferentially to the Si(110) crystal orientation; and
extending the silicon-containing material over the second region.

2. The method of claim 1, wherein the silicon-containing material comprises a ratio of the Si(100) crystal orientation to the Si(110) crystal orientation of between about 1.6 and 3.5.

3. The method of claim 1, wherein a crystal structure of the silicon-containing material is substantially homogeneous in the Si(100) crystal orientation.

4. The method of claim 1, wherein the non-(110) crystal orientation is polycrystalline, amorphous, or a Si(111) crystal orientation, or a combination thereof.

5. The method of claim 1, wherein extending the silicon-containing material over the second region further comprises forming a conformal layer of the silicon-containing material overlying the surface.

6. The method of claim 1, wherein the first regions comprise monocrystalline silicon.

7. The method of claim 1, wherein the second region comprises a dielectric material.

8. The method of claim 7, wherein the dielectric material comprises at least one of SiN, SiOxNy, and SiOx, or a combination thereof.

9. The method of claim 7, wherein the dielectric material is a nitride or an oxide, or a combination thereof.

10. The method of claim 1, wherein extending the silicon-containing material over the second region further comprises forming a conformal layer of the silicon-containing material overlying the surface, wherein the conformal layer is an n-doped or p-doped barrier layer.

11. The method of claim 10, wherein epitaxially growing the silicon-containing material further comprises:
a. flowing a selective silicon precursor into the chamber;
b. flowing one or more dopant-containing precursors into the chamber; and
c. contacting the surface with the selective silicon precursor and the one or more dopant-containing precursors at a pressure of about between about 200 and 300 torr until a predetermined thickness of the conformal layer is achieved.

12. The method of claim 11, wherein the selective silicon precursor is dichlorosilane (DCS).

13. The method of claim 11, wherein the predetermined thickness of the conformal layer is about 1.0 nm to about 10.0 nm.

14. The method of claim 11, wherein the one or more dopant-containing precursors comprise a p-type metal-oxide-semiconductor (pMOS) precursor comprising diborane (B2H6) or boron trichloride (BCl3), or a combination thereof.

15. The method of claim 11, wherein the one or more dopant-containing precursors are n-type metal-oxide-semiconductor (nMOS) precursors comprising phosphine (PH3) or arsine (AsH3), or a combination thereof.

16. The method of claim 15, wherein PH3 and AsH3 are co-flowed.

17. The method of claim 15, wherein AsH3 is flowed without PH3.

18. The method of claim 11, further comprising inhibiting epitaxial growth of the silicon-containing material in the Si(110) crystal orientation, wherein inhibiting epitaxial growth of the silicon-containing material in the Si(110) crystal orientation further comprises:
a. flowing HCl into the chamber; and
b. etching the silicon-containing material in the Si(110) crystal orientation, wherein the selective silicon precursor and the HCl are co-flowed into the chamber in a ratio of about 1.5 to 6.

19. A semiconductor processing system, comprising:
a. a chamber configured to support a substrate, wherein the substrate comprises a feature having a surface including at least two first regions comprising silicon in a Si(110) crystal orientation and at least one second region comprising silicon in a non-Si(110) crystal orientation, wherein the at least one second region is disposed between the first regions;
b. a selective silicon precursor source, a first dopant source, a second dopant source and an etchant source connected to the chamber; and
c. a controller operably connected to the selective silicon precursor source, the first dopant source, the second dopant source, and the etchant source, wherein the controller, responsive to instructions recorded on a memory, is to:
i. support a substrate within the chamber at a pressure of about 200 to 300 torr;
ii. flow a selective silicon precursor into the chamber to contact the at least two first regions;
iii. form a silicon-containing material in a Si(100) crystal orientation on the at least two first regions wherein the silicon-containing material extends from the at least two first regions across the second region forming a continuous barrier layer over the surface to a predetermined thickness;
iv. flow one or more dopant-containing precursors into the chamber to deposit one or more dopant species in the silicon-containing material; and
v. flow an etchant into the chamber to etch the silicon-containing material in the Si(110) crystal orientation.

20. The semiconductor processing system of claim 19, wherein the continuous barrier layer comprises a ratio of the Si(100) crystal orientation to the Si(110) crystal orientation of about 1.6 and 3.5, and wherein the selective silicon precursor is DCS, the one or more dopant-containing precursors are PH3 and AsH3, and the etchant is HCl.
